(19) United States
(12) Patent Application Publication
(10) Pub. No.: US 2014/0352786 A1
(43) Pub. Date: Dec. 4, 2014

(54) ZnO-BASED SPUTTERING TARGET AND PHOTOVOLTAIC CELL HAVING PASSIVATION LAYER DEPOSITED USING THE SAME

(71) Applicant: SAMSUNG CORNING ADVANCED GLASS, LLC, Chungcheongnam-do (KR)

(72) Inventors: YoonGyu Lee, Chungcheongnam-do (KR); Hwangyong Go, Chungcheongnam-do (KR); Juok Park, Chungcheongnam-do (KR); Soo Young Seo, Chungcheongnam-do (KR)

(73) Assignee: SAMSUNG CORNING ADVANCED GLASS, LLC, Chungcheongnam-do (KR)

(21) Appl. No.: 14/287,673

(22) Filed: May 27, 2014

(30) Foreign Application Priority Data
May 28, 2013 (KR) 10-2013-0060477

(51) Int. Cl. H01L 31/0216

(52) U.S. Cl. CPC H01L 31/02167
USPC 136/262; 204/298.13

(57) ABSTRACT

A zinc oxide (ZnO)-based sputtering target which is available for DC sputtering and a photovoltaic cell having a passivation layer deposited using the same. The ZnO-based sputtering target includes a sintered body made of ZnO, the ZnO being doped with 10 to 60% by weight gallium oxide, and a backing plate bonded to the rear surface of the sintered body to support the sintered body. The passivation layer can prevent a change in the composition of the light-absorbing layer from lowering an efficiency.

### CROSS REFERENCE TO RELATED APPLICATION

The present application claims priority from Korean Patent Application Number 10-2013-0060477 filed on May 28, 2013, the entire contents of which are incorporated herein for all purposes by this reference.

### BACKGROUND OF THE INVENTION

1. Field of the Invention

The present invention relates to a zinc oxide (ZnO)-based sputtering target and a photovoltaic cell having a passivation layer deposited using the same, and more particularly, to a ZnO-based sputtering target available for direct current (DC) sputtering and a photovoltaic cell having a passivation layer deposited using the same, in which the passivation layer can prevent a change in the composition of a light-absorbing layer from lowering an efficiency.

2. Description of Related Art

Recently, as a countermeasure to the shortage of energy resources and to environmental pollution, the development of high-efficiency photovoltaic cells is underway on a large scale. A photovoltaic cell is a key device for photovoltaic power generation that directly converts solar energy into electricity. While demand for photovoltaic modules is rapidly increasing, the necessity to increase their size is also increasing.

A photovoltaic cell module can have a multilayer structure including a cover glass, a first buffering member, a cell stack, a second buffering member and a rear sheet. The cell stack can include a substrate, a common electrode, a light-absorbing layer, a buffer layer, a passivation layer and a transparent electrode. The substrate can be made of glass or steel. The common electrode can be formed by depositing molybdenum (Mo) on the substrate. The light-absorbing layer can be formed by depositing, for example, a copper indium gallium selenide (CIGS) compound on the common electrode by means of sputtering, molecular beam epitaxy (MBE) or evaporation. The buffer layer can be formed by depositing cadmium sulfide (CdS) or zinc sulfide (ZnS) on the light-absorbing layer by chemical bath deposition (CBD) or atomic layer deposition (ALD). The passivation layer can be formed by depositing intrinsic zinc oxide (i-ZnO) on the buffer layer.

The i-ZnO used for the passivation layer of the cell stack is a nonconductor, the electrical characteristics of which conflict with those of the transparent electrode which is made of, for example, a ZnO-based thin film.

In addition, the light-absorbing layer made of a CIGS compound has an unstable composition due to, for example, the interfacial diffusion of gallium (Ga). When the composition of the light-absorbing layer changes in this manner, the efficiency of a photovoltaic cell must be lowered. Accordingly, solutions that can prevent the composition of the light-absorbing layer from changing are urgently required.

The information disclosed in the Background of the Invention section is provided only for better understanding of the background of the invention, and should not be taken as an acknowledgment or any form of suggestion that this information forms a prior art that would already be known to a person skilled in the art.

### RELATED ART DOCUMENT

Patent Document 1: Japanese Patent No. 4670877 (Jan. 28, 2011)

### BRIEF SUMMARY OF THE INVENTION

Various aspects of the present invention provide a zinc oxide (ZnO)-based sputtering target available for direct current (DC) sputtering and a photovoltaic cell having a passivation layer deposited using the same, in which the passivation layer can prevent a change in the composition of a light-absorbing layer from lowering an efficiency.

In an aspect of the present invention, provided is a ZnO-based sputtering target that includes a sintered body made of ZnO, the ZnO being doped with 10 to 60% by weight gallium oxide, and a backing plate bonded to the rear surface of the sintered body to support the sintered body.

According to an embodiment of the present invention, the resistivity of the sintered body may be 100 Ω·cm or less.

The ZnO-based sputtering target may be available for DC sputtering.

The bending strength of the sintered body may be 50 MPa or greater.

Gallium oxide aggregates having a diameter of 1 μm may be distributed inside the sintered body, the volume of the gallium oxide aggregates being less than 5% of the volume of the sintered body.

In another aspect of the present invention, provided is a photovoltaic cell that includes a ZnO-based thin film doped with 10 to 60% by weight gallium oxide as a passivation layer.

According to an embodiment of the present invention, the photovoltaic cell may further include a light-absorbing layer made of a CIGS compound.

The size of crystal grains of the passivation layer may be 10 nm or greater

The thickness of the passivation layer may be less than 100 nm.

The thickness of the passivation layer may be less than 50 nm.

The resistivity of the passivation layer may be 10 Ω·cm or less.

According to embodiments of the present invention, DC sputtering can be performed reliably by doping ZnO with 10 to 60% by weight gallium oxide.

In addition, since the ZnO-based thin film is deposited as the passivation layer using the ZnO-based sputtering target, the high concentration of Ga contained in the passivation layer can prevent the composition of the unstable light-absorbing layer from changing, thereby preventing the efficiency of the photovoltaic cell from decreasing.

Furthermore, since the uniformity of the composition of the passivation layer deposited using the ZnO-based sputtering target is increased, it is possible to fabricate a photovoltaic cell having a large area.

In addition, the ZnO-based thin film doped with gallium oxide is deposited as the passivation layer using the sputtering target. Consequently, when the ZnO-based thin film is deposited as the transparent electrode on the conductive passivation layer, it is possible to reduce the resistance of the transparent electrode and thus improve the photoelectric conversion efficiency of the photovoltaic cell.

Furthermore, since the ZnO-based thin film, to which a large amount of gallium oxide is added, is used as the passivation layer, it is possible to reduce the interfacial diffusion of Ga contained in the light-absorbing layer made of the CIGS compound. The Ga in the passivation layer can diffuse into the light-absorbing layer, thereby improving the efficiency of the photovoltaic cell.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a conceptual cross-sectional view schematically showing a photovoltaic cell having a passivation layer that is deposited using a zinc oxide (ZnO)-based sputtering target according to an exemplary embodiment of the present invention.

### DETAILED DESCRIPTION OF THE INVENTION

Reference will now be made in detail to a zinc oxide (ZnO)-based sputtering target and a photovoltaic cell having a passivation layer deposited using the same according to the present invention, embodiments of which are illustrated in the accompanying drawings and described below, so that a person skilled in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

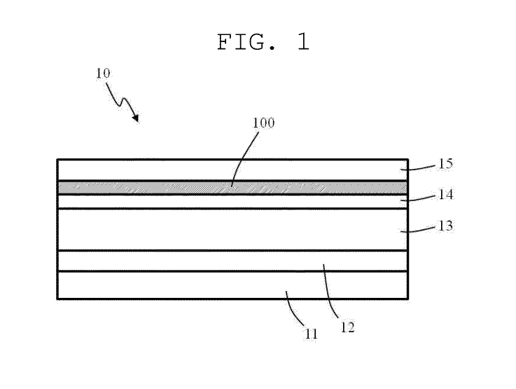

A ZnO-based sputtering target according to an exemplary embodiment of the present invention is a target that is used for depositing a passivation layer 100 in a photovoltaic cell 10 shown in FIG. 1. As shown in FIG. 1, the photovoltaic cell 10 includes a substrate 11, a common electrode 12, a light-absorbing layer 13, a buffer layer 14, the passivation layer 100 and a transparent electrode 15. The passivation layer 100 is formed as a ZnO-based thin film, the composition of which includes, by weight, 10 to 60% gallium oxide. In the photovoltaic cell 10, the substrate 11 can be made of glass or steel. The common electrode 12 can be formed on the substrate 11 by depositing molybdenum (Mo). The light-absorbing layer 13 can be formed on the common electrode 12 by depositing a copper indium gallium selenide (CIGS) compound by means of sputtering, molecular beam epitaxy (MBE) or evaporation. The buffer layer 14 can be formed on the light-absorbing layer 13 by depositing, for example, cadmium sulfide (CdS) or zinc sulfide (ZnS) on the light-absorbing layer 13 by chemical bath deposition (CBD) or atomic layer deposition (ALD). The transparent electrode 15 can be deposited on the passivation layer 100 which is deposited using the ZnO-based sputtering target according to this exemplary embodiment. The transparent electrode 15 can be formed as a ZnO-based thin film like the passivation layer 100.

As such, the ZnO-based sputtering target according to this exemplary embodiment is used for the deposition of the passivation layer 100 of the photovoltaic cell 10, and includes a sintered body and a backing plate.

The sintered body is made of ZnO that is doped with 10 to 60% by weight gallium oxide. When ZnO is doped with gallium oxide, Ga from gallium oxide substitutes for Zn in the ZnO structure, thereby forming an n-type semiconductor to which electrical conductivity is imparted. Since the Ga content in ZnO is limited in the thermodynamic equilibrium state, the amount of gallium oxide added is controlled such that the sintered body made of ZnO is electrically conductive, which in turn makes the sintered body available for direct current (DC) sputtering. If the amount of gallium oxide added is 10% by weight or greater, it is advantageous to improve the efficiency of the CIGS light-absorbing layer 13. However, since the resistivity of the sintered body significantly increases if the amount of gallium oxide added exceeds 60% by weight, it is preferred that the amount of gallium oxide added be controlled to be 60% by weight or less. In contrast, if the amount of gallium oxide added is less than 10% by weight, the ability of gallium oxide to improve the efficiency of the CIGS light-absorbing layer 13 is limited although the low resistivity of the ZnO sintered body allows reliable discharge. Then, it is impossible to prevent the unstable composition of the light-absorbing layer 13 from changing.

Accordingly, it is possible to deposit a ZnO-based thin film doped with 10 to 60% by weight gallium oxide as the passivation layer 100 of the photovoltaic cell 10 using the sputtering target having the sintered body made of ZnO that is doped with 10 to 60% by weight gallium oxide.

It is preferred that the amount of gallium oxide added to the ZnO-based sintered body be controlled such that the sintered body has a bending strength of 50 MPa or greater so that the sintered body is safe from the danger of cracking due to high power induced during sputtering and gallium oxide aggregates having a diameter of 1 μm or greater are distributed inside the sintered body and have a volume less than 5% of the volume of the sintered body.

The backing plate is a member that serves to support the sintered body, and can be made of Cu, preferably, oxygen-free Cu, Ti or stainless steel that has superior electrical and thermal conductivity. The backing plate is bonded to the rear surface of the sintered body by means of a bonding material made of, for example, In, thereby forming the ZnO-based sputtering target.

The ZnO-based sputtering target including the sintered body and the backing plate has a high deposition rate. The resistivity of the sintered body is 100 Ω·cm or less, which enables the discharge to be reliably conducted without abnormal discharge when high power is induced during sputtering. This consequently increases the composition uniformity of the deposited passivation layer 100, and thus the photovoltaic cell 10 having a large area can be fabricated.

The passivation layer 100 of the photovoltaic cell 10 that is deposited using the ZnO-based sputtering target according to this exemplary embodiment can have a resistivity of 10 Ω·cm or less. The superior resistance characteristic of the passivation layer 100 also decreases the resistance of the overlying transparent electrode 15. This can consequently prevent the efficiency of a copper indium gallium selenide (CIGS) layer from being reduced due to the high resistance of the transparent electrode, which would otherwise occur when a large panel is applied in the related art.

The passivation layer 100 can have a thickness less than 100 nm, preferably, less than 50 nm. This is because the passivation layer 100, together with the buffer layer 14, allows light to pass through and a smaller thickness is more advantageous for the passivation layer 100 to increase the transmittance.

The passivation layer 100 formed as the ZnO-based thin film that is deposited using the ZnO-based sputtering target maintains the hexagonal crystal structure of ZnO regardless of the Ga content, in which crystals grow generally along the c-axis. In this case, the size of crystal grains of the passivation layer 100 can be 10 nm or greater.

The passivation layer 100 deposited using the ZnO-based sputtering target according to this exemplary embodiment has the crystal structure based on ZnO. The transparent electrode 15 deposited on the passivation layer 100 can be formed as a ZnO-based thin film like the passivation layer 100. Accordingly, the transparent electrode 15 is deposited on the passivation layer 100 that has a crystal orientation from the early stage of the deposition process, and thus the performance of the transparent electrode 15 can be maximized, thereby further improving the photoelectric conversion efficiency of the photovoltaic cell 10.

In addition, in the passivation layer 100 deposited using the ZnO-based sputtering target according to this exemplary embodiment, the high concentration of Ga can prevent the composition change of the light-absorbing layer 13 that is made of a CIGS compound having an unstable composition. Specifically, when the passivation layer 100 for the light-absorbing layer 13 made of the CIGS compound is formed as a ZnO-based thin film to which a large amount of gallium oxide is added, it is possible to reduce the interfacial diffusion of Ga contained in the light-absorbing layer 13. In addition, Ga in the passivation layer 100 can diffuse into the light-absorbing layer 13, thereby improving the efficiency of the photovoltaic cell 10.

### EXAMPLE 1

A buffer layer was formed by depositing cadmium sulfide (CdS) on a light-absorbing layer made of a copper indium gallium selenide (CIGS) compound. A passivation layer was formed on the buffer layer by direct current (DC) sputtering using a gallium oxide-doped zinc oxide (GZO) target. A transparent electrode (TCO) was formed on the passivation layer by DC sputtering using a Ga—Al—Zn—O (GAZO) target. Afterwards, the characteristics of the resultant structure were analyzed.

### Comparative Example 1

A buffer layer was formed by depositing CdS on a light-absorbing layer made of a CIGS compound. A passivation layer was formed on the buffer layer by radio frequency (RF) sputtering using an intrinsic zinc oxide (i-ZnO) gallium target. A TCO was formed on the passivation layer by RF sputtering using an Al—Zn—O (AZO) target.

Afterwards, the characteristics of the resultant structure were analyzed.

### Comparative Example 2

buffer layer was formed by depositing CdS on a light-absorbing layer made up of a CIGS compound. A passivation layer was formed on the buffer layer by RF sputtering using an i-ZnO gallium target. A TCO was formed on the passivation layer by RF sputtering using a GAZO target. Afterwards, the characteristics of the resultant structure were analyzed.

TABLE 1

| | TCO | | | | | | |
|---|---|---|---|---|---|---|---|
| | power | TCO | Buffer | i-ZnO | | GZO | |
| | density | thickness | layer | Deposition | thickness | Deposition | thickness |
| | (W/cm²) | (Å) | type | method | (Å) | method | (Å) |
| AZO | 4.4 | 5000 | CdS | RF | 800 | — | — |
| GAZO | 4.4 | 5000 | CdS | RF | 800 | DC | 800 |

TABLE 2

| | Comp. Example 1 | Comp. Example 2 | Example 1 |
|---|---|---|---|
| V_{oc} (V) | 0.52 | 0.57 | 0.65 |
| J_{sc} (ma/cm²) | 34.31 | 33.01 | 33.66 |
| FF (%) | 64.32 | 66.89 | 70.81 |
| Efficiency (%) | 11.56 | 12.52 | 15.24 |

Table 1 above presents deposition conditions, and Table 2 above presents characteristics analysis results.

Referring to FIG. 2, both the open-circuit voltage V_{oc} and the fill factor (FF) were measured as higher and the short-circuit current J_{sc} was measured as lower in Comparative Example 2 in which the transparent electrode (TCO) was made of GAZO than in Comparative Example 1 in which the transparent electrode was made of AZO. Accordingly, the efficiency of Comparative Example 2 was improved by about 1% over that of Comparative Example 1. This explains that it is preferable to make the transparent electrode from GAZO than AZO in order to improve the efficiency of the photovoltaic cell.

Referring to Example 1 in which the transparent electrode was formed by depositing GAZO as in Comparative Example 2 and the passivation layer was formed by depositing GZO, both the open-circuit voltage V_{oc} and the fill factor (FF) were measured as higher than those of Comparative Example 2, and short-circuit current J_{sc} was measured as similar to that of Comparative Example 2. Accordingly, the efficiency of Example 1 was improved by about 2.7% over that of in Comparative Example 2. In addition, the efficiency of the photovoltaic cell of Example 1 was improved by about 3.75% over that of the photovoltaic cell having the AZO/i-ZnO structure according to Comparative Example 1.

As set forth above, it is proved that substituting GZO for i-ZnO in the passivation layer is more effective than substituting GAZO for AZO in the transparent electrode in terms of the efficiency of the photovoltaic cell. In other words, the deposition of GZO for the passivation layer can improve the electrical characteristics of the transparent electrode made of GAZA and maximize the effect of Ga, thereby preventing the composition of the light-absorbing layer made of a CIGS compound from changing.

The foregoing descriptions of specific exemplary embodiments of the present invention have been presented with respect to the drawings. They are not intended to be exhaustive or to limit the present invention to the precise forms disclosed, and obviously many modifications and variations are possible for a person having ordinary skill in the art in light of the above teachings.

It is intended therefore that the scope of the present invention not be limited to the foregoing embodiments, but be defined by the Claims appended hereto and their equivalents.

What is claimed is:

1. A zinc oxide-based sputtering target, comprising:
a sintered body comprising zinc oxide doped with 10 to 60 weight percent gallium oxide based on the weight of the sintered body; and
a backing plate bonded to a rear surface of the sintered body to support the sintered body.

2. The zinc oxide-based sputtering target according to claim 1, wherein a resistivity of the sintered body is 100 Ω·cm or less.

3. The zinc oxide-based sputtering target according to claim 1, the zinc oxide-based sputtering target being available for direct current sputtering.

4. The zinc oxide-based sputtering target according to claim 1, wherein a bending strength of the sintered body is 50 MPa or greater.

5. The zinc oxide-based sputtering target according to claim 1, wherein aggregates of the gallium oxide having a diameter of 1 μm are distributed inside the sintered body, a volume of the aggregates of the gallium oxide being less than 5% of a volume of the sintered body.

6. A photovoltaic cell comprising a zinc oxide-based thin film doped with 10 to 60 weight percent gallium oxide based on the weight of the zinc oxide-based thin film as a passivation layer.

7. The photovoltaic cell according to claim 6, further comprising a light-absorbing layer comprising a copper indium gallium selenide compound.

8. The photovoltaic cell according to claim 6, wherein a size of crystal grains of the passivation layer is 10 nm or greater.

9. The photovoltaic cell according to claim 6, wherein a thickness of the passivation layer is less than 100 nm.

10. The photovoltaic cell according to claim 9, wherein a thickness of the passivation layer is less than 50 nm.

11. The photovoltaic cell according to claim 6, wherein a resistivity of the passivation layer is 10 Ω·cm or less.
